(19) United States
(12) Patent Application Publication
(10) Pub. No.: US 2010/0127317 A1
(43) Pub. Date: May 27, 2010

(54) SEMICONDUCTOR DEVICE AND METHOD FOR MANUFACTURING THE SAME

(75) Inventor: Yasushi YAMAZAKI, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/626,797

(22) Filed: Nov. 27, 2009

(30) Foreign Application Priority Data
Nov. 27, 2008 (JP) 2008-302717

(51) Int. Cl. H01L 27/108; H01L 21/02

(52) U.S. Cl. 257/306; 438/396; 257/E27.084; 257/E21.008

(57) ABSTRACT

A semiconductor device includes a memory cell array region including a plurality of memory cells, an annular groove surrounding the memory cell array region, a protective insulating film covering the inner wall of the annular groove, and a conductor filling the annular groove.

### BACKGROUND OF THE INVENTION

1. Field of the Invention

The present invention relates to a semiconductor device and a method for manufacturing the same.

2. Description of Related Art

In recent years, a DRAM memory cell uses a capacitor having a three-dimensional structure as the size of the cell decreases. A currently dominant capacitor structure of this type is a crown structure.

A capacitor having a crown structure (hereinafter referred to as a “crown capacitor”) includes a tubular lower electrode (storage electrode), a dielectric film that covers the inner and outer circumferential surfaces of the lower electrode, and an upper electrode (counter electrode) on the dielectric film. For example, Japanese Patent Laid-Open No. 11-026718 (Patent Document 1) and Japanese Patent Laid-Open No. 2000-196038 (Patent Document 2) describe the structure of a crown capacitor and a method for manufacturing the same.

An exemplary method for forming the lower electrode of a crown capacitor will be described with reference to FIGS. 1A to 2B.

First, holes 31 and a guard ring groove 32 are formed in an interlayer insulating film 30, and a conductive film 40 made of TiN, DOPOS (doped polycrystalline silicon), or any other suitable material is formed on the inner walls of the holes 31 and the guard ring groove 32 (FIG. 1A). In FIG. 1A, reference numeral 20 denotes an underlying insulating film, and reference numeral 21 denotes a plug. Each of the holes 31 is formed in the position corresponding to a lower electrode, which will be formed later, and the guard ring groove 32 is formed in such a way that it surrounds a memory cell array region.

An insulating film 50 is formed to fill the holes 31 and the guard ring groove 32, and then a resist film 60 is formed to cover the region (peripheral region) outside the memory cell array region. Etching is carried out over the surface using the resist film 60 as a mask to remove the conductive film 40 other than those in the holes 31 and the guard ring groove 32 so that the interlayer insulating film 30 is exposed (FIG. 1B). In this process, the end of the resist film 60 is positioned above the guard ring groove. The resist film 60 therefore protects the conductive film 40 in the guard ring groove and in the peripheral region when the etching is carried out.

After the resist film 60 is removed, wet etching is carried out to remove not only the insulating film 50 in the holes 31, in the guard ring groove 32, and on the peripheral region but also the interlayer insulating film 30 between the holes 31 and between the guard ring groove 32 and the holes 31 adjacent thereto. As a result, the remaining conductive film 40 forms lower electrodes 41 and a protective conductive film 42 that covers the interlayer insulating film 30 in the peripheral region (FIG. 2B). In the wet etching, the protective conductive film 42 functions as an etching stopper film, whereby the interlayer insulating film 30 in the peripheral region covered with the protective conductive film 42 will not be etched but left.

FIG. 2A is a transverse cross-section view (taken along the line B-B in FIG. 2B) corresponding to FIG. 2B showing the state at this point. FIGS. 1A, 1B, and 2B correspond to cross-sectional views taken along the line A-A in FIG. 2A.

Leaving the interlayer insulating film 30 in the peripheral region prevents any stepped portion from being formed between the memory cell array region and the peripheral region, and thus allows planarization to be readily carried out.

### SUMMARY

In the method described above, however, when the lower electrodes 41 are made of TiN or any other conductive material that is prone to cracking, the conductive film 42, which covers the interlayer insulating film 30 in the peripheral region, is also prone to cracking because the conductive film 42 is made of the same material. In this case, the etchant disadvantageously penetrates the interlayer insulating film in the peripheral region through the produced cracks. As a result, voids 33 are created in the interlayer insulating film 30 in the peripheral region, as shown in FIG. 2B, resulting in reduction in yield and reliability of the device. When the lower electrodes are made of polycrystalline silicon, and the demand for miniaturization forces the film thickness of each of the lower electrodes to be smaller than 50 nm, a problem of penetration of a chemical solution through grain boundaries occurs.

Patent Document 2 (Japanese Patent Laid-Open No. 2000-196038) describes that the guard ring groove is filled with W, TiN, or any other suitable metallic material. However, a film made of a metallic material has pores, through which the etchant tends to penetrate. When the demand for miniaturization forces the film thickness in the guard ring groove to be thin, it is difficult to adequately prevent the etchant from penetrating.

In one embodiment, there is provided a semiconductor device including:
a memory cell array region including a plurality of memory cells;
an annular groove surrounding the memory cell array region;
a protective insulating film covering the inner wall of the annular groove; and
a conductor filling the annular groove.

In another embodiment, there is provided the semiconductor device as described above, wherein the outer circumferential side surface in the annular groove is formed of a side surface of a peripheral insulating layer surrounding the memory cell array region; and the protective insulating film covers the side surface and the upper surface of the peripheral insulating layer.

In another embodiment, there is provided the semiconductor device as described above, wherein each of the memory cells includes a capacitor;
the capacitor includes a tubular storage electrode, a dielectric film covering the inner side surface and the outer side surface of the tubular storage electrode, and a counter electrode on the dielectric film;
the outer circumferential side surface in the annular groove is formed of a side surface of a peripheral insulating layer surrounding the memory cell array region;
the inner circumferential side surface in the annular groove is formed of a side surface of an inner conductive layer;
a sidewall conductive film made of the same material as that of the storage electrode is formed on the side surface of the peripheral insulating layer;
the protective insulating film covers the side surface and the upper surface of the peripheral insulating layer, the sidewall conductive film being disposed between the protective insulating film and the side surface of the peripheral insulating layer; and
the counter electrode, the conductor filling the annular groove, and the side surface of the inner conductive layer are made of the same material and formed integrally with one another.

In another embodiment, there is provided the semiconductor device as described above, wherein a support insulating film pattern is formed from the upper end of each of the tubular storage electrodes to the upper end of at least one of the other tubular storage electrodes adjacent to the tubular storage electrode, the support insulating film pattern being in contact with both the upper ends, without overlapping with the inner region of any of the tubular storage electrodes.

In the semiconductor device described above, the support insulating film pattern may be made of the same material as that of the protective insulating film. The support insulating film pattern may be continuous with the protective insulating film. The support insulating film pattern may be formed of a stacked film including a first support film pattern and a second support film pattern on the first support film pattern, and the second support film pattern may be made of the same material as that of the protective insulating film. The second support film pattern may be continuous with the protective insulating film.

In another embodiment, there is provided a semiconductor device including:
a memory cell array region including a plurality of memory cells;
a peripheral insulating layer provided on an underlying insulating film;
an annular stepped portion formed of a side surface of the peripheral insulating layer, the annular stepped portion surrounding the memory cell array region, and
a protective insulating film formed on the side surface and the upper surface of the peripheral insulating layer, the protective insulating film covering the stepped portion,
wherein each of the memory cells includes a capacitor including
   a tubular storage electrode connected to a plug passing through the underlying insulating film,
   a dielectric film covering the inner side surface and the outer side surface of the storage electrode, and
   a counter electrode on the dielectric film.

In another embodiment, there is provided the semiconductor device as described above, wherein a sidewall conductive film made of the same material as that of the storage electrode is formed on the side surface of the peripheral insulating layer, the side surface forming the stepped portion; and the protective insulating film is provided over the side surface of the peripheral insulating layer, the sidewall conductive film being disposed between the protective insulating film and the side surface of the peripheral insulating layer.

In another embodiment, there is provided the semiconductor device as described above, wherein a support insulating film pattern is formed from the upper end of each of the tubular storage electrodes to the upper end of at least one of the other tubular storage electrodes adjacent to the tubular storage electrode, the support insulating film pattern being in contact with both the upper ends, without overlapping with the inner region of any of the tubular storage electrodes.

In the semiconductor device described above, the support insulating film pattern may be made of the same material as that of the protective insulating film. The support insulating film pattern may be continuous with the protective insulating film. The support insulating film pattern may be formed of a stacked film including a first support film pattern and a second support film pattern on the first support film pattern, and the second support film pattern may be made of the same material as that of the protective insulating film. The second support film pattern may be continuous with the protective insulating film.

In another embodiment, there is provided a method for manufacturing a semiconductor device including:
forming an underlying insulating film on a semiconductor substrate;
forming a plurality of plugs passing through the underlying insulating film;
forming an interlayer insulating film on the underlying insulating film;
forming a plurality of holes and an annular groove in the interlayer insulating film, the holes reaching the respective plugs, the annular groove surrounding the holes and reaching the underlying insulating film;
forming a first conductive film on the surface including the inner surfaces of the holes and the annular groove;
removing the first conductive film other than those in the holes and the annular groove such that a plurality of tubular conductors formed of the first conductive film are left in the holes;
forming a protective insulating film covering the inner surface of the annular groove and the interlayer insulating film outside the annular groove;
carrying out isotropic etching with the protective insulating film used as a mask to remove the interlayer insulating film inside the annular groove such that the tubular conductors are exposed;
forming a dielectric film on the inner side surface and the outer side surface of each of the tubular conductors; and
forming a second conductive film on the dielectric film.

In the formation of the protective insulating film in the manufacturing method described above, a pattern including the following portions may be formed:
a protective pattern that covers the inner surface of the annular groove and the interlayer insulating film outside the annular groove, and
a support pattern extending from the upper end of each of the tubular conductors to the upper end of at least one of the other tubular conductors adjacent to the tubular conductor, the support insulating film pattern being in contact with both the upper ends, without overlapping with the inner region of any of the tubular conductors.

According to exemplary embodiments, a semiconductor device having a structure that can be readily formed at a high yield and having high storage capacity can be provided.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a partial cross-sectional view showing a structure in the middle of manufacturing processes for explaining related art;

FIG. 1B is a partial cross-sectional view showing the structure obtained after the step subsequent to the step of forming the structure shown in FIG. 1A;

FIG. 2A is a partial cross-sectional view (transverse cross-sectional view) showing the structure obtained after the step subsequent to the step of forming the structure shown in FIG. 1B;

FIG. 2B is a partial cross-sectional view (vertical cross-sectional view) showing the structure obtained after the step subsequent to the step of forming the structure shown in FIG. 1B;

FIG. 3A is a partial cross-sectional view showing a structure in the middle of manufacturing processes for explaining an embodiment of the present invention;

FIG. 3B is a partial cross-sectional view showing the structure obtained after the step subsequent to the step of forming the structure shown in FIG. 3A;

FIG. 3C is a partial cross-sectional view showing the structure obtained after the step subsequent to the step of forming the structure shown in FIG. 3B;

FIG. 3D is a partial cross-sectional view showing the structure obtained after the step subsequent to the step of forming the structure shown in FIG. 3C;

FIG. 3E is a partial cross-sectional view showing the structure obtained after the step subsequent to the step of forming the structure shown in FIG. 3D;

FIG. 3F is a partial cross-sectional view showing the structure obtained after the step subsequent to the step of forming the structure shown in FIG. 3E;

FIG. 3G is a partial cross-sectional view showing the structure obtained after the step subsequent to the step of forming the structure shown in FIG. 3F;

FIG. 4A is a partial plan view showing the structure obtained after the step subsequent to the step of forming the structure shown in FIG. 3G;

FIG. 4B is a partial cross-sectional view showing the structure obtained after the step subsequent to the step of forming the structure shown in FIG. 3G;

FIG. 5 is a partial cross-sectional view showing the structure obtained after the step subsequent to the step of forming the structure shown in FIGS. 4A and 4B;

FIG. 6A is a partial cross-sectional view showing a structure in the middle of manufacturing processes for explaining another embodiment of the present invention;

FIG. 6B is a partial cross-sectional view showing the structure obtained after the step subsequent to the step of forming the structure shown in FIG. 6A;

FIG. 6C is a partial cross-sectional view showing the structure obtained after the step subsequent to the step of forming the structure shown in FIG. 6B;

FIG. 6D is a partial cross-sectional view showing the structure obtained after the step subsequent to the step of forming the structure shown in FIG. 6C; and

FIG. 7 is a partial cross-sectional view showing the structure obtained after the step subsequent to the step of forming the structure shown in FIG. 6D.

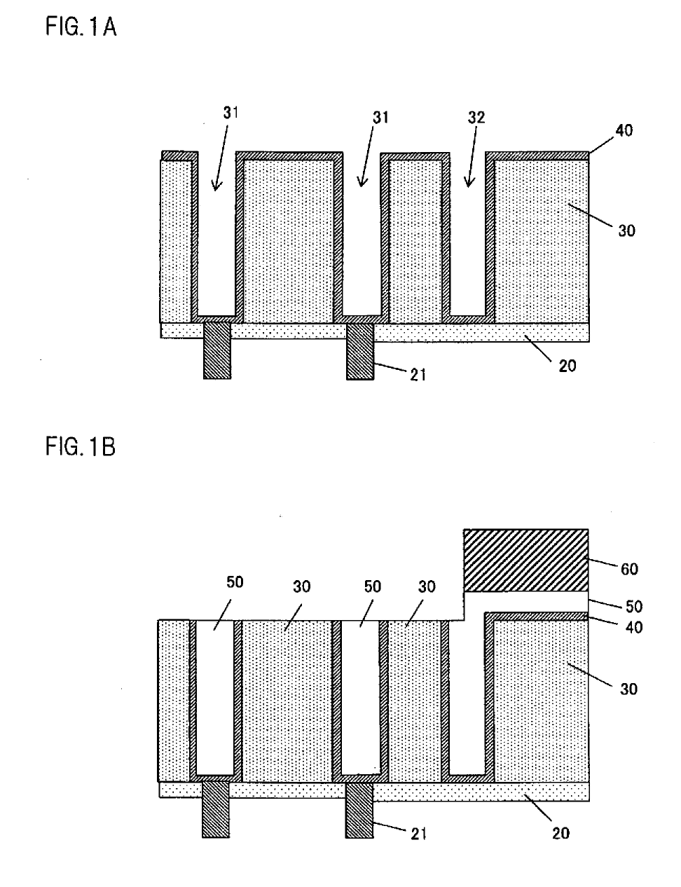

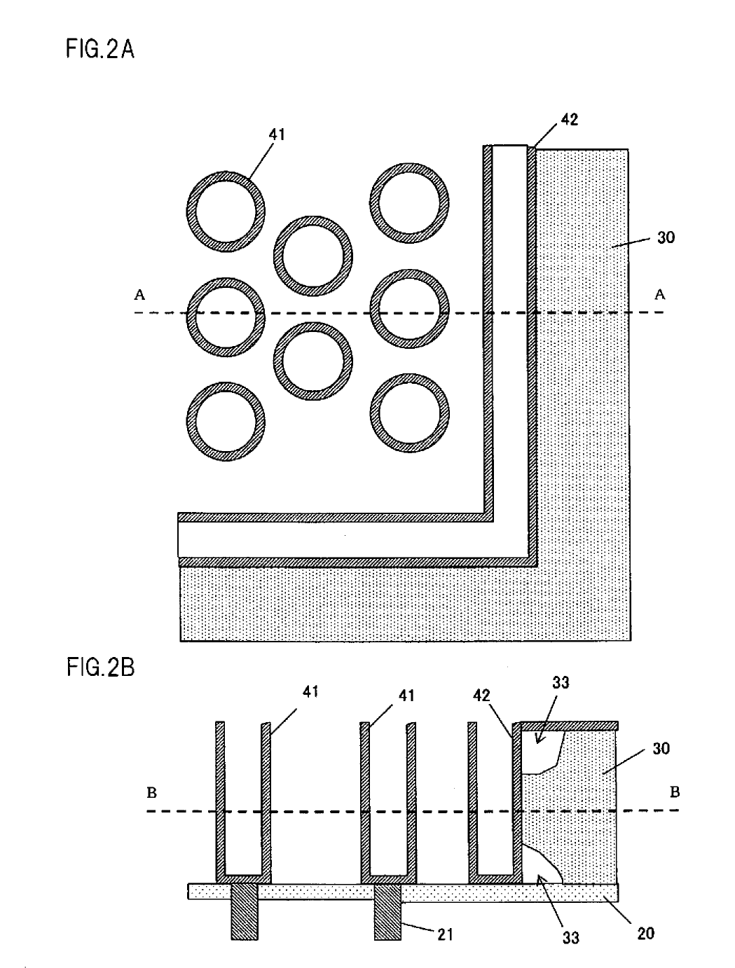

### DETAILED DESCRIPTION OF THE PREFERRED EMBODIMENTS

As a preferred embodiment of the present invention, a description will be made of a semiconductor device with a memory cell array in which a plurality of memory cells are formed, each of the memory cells including a tubular storage electrode, a dielectric film that covers the inner and outer circumferential surfaces of the tubular storage electrode, and a counter electrode on the dielectric film. The term “tubular” used herein means a hollow shape. The “tubular” shape viewed from the above is not limited to a circle but may be an ellipse, a square, a rectangle, a parallelogram, or any other rectangle, or any other polygon. The tubular storage electrode of the present embodiment has a cylindrical structure extending in the direction perpendicular to a substrate plane and having an opening in the upper end and a bottom portion integrated with the side surface in the lower end. The bottom portion is in contact with a contact plug electrically connected to a memory cell transistor.

The semiconductor device of the present embodiment includes an annular groove (guard ring groove) 132 that surrounds the outer side of a memory cell array region, as shown in FIG. 5, and the inner wall of the groove is covered with a protective nitride film 150. The guard ring groove 132 is filled with the material (buried conductor) of a counter electrode 170 in accordance with manufacturing processes, which will be described later.

An outer circumferential sidewall film 133b and an inner circumferential sidewall film 133c in the guard ring groove are formed of a conductive film made of the same material as that of each tubular storage electrode 133a, and the protective nitride film 150 is formed to cover at least the outer circumferential sidewall film 133b.

The outer circumferential sidewall conductive film 133b in the guard ring groove is formed on the side surface of an interlayer insulating film (peripheral insulating layer) 130 disposed around the memory cell array region. That is, the side surface of the peripheral insulating layer forms an annular stepped portion that surrounds the outer side of the memory cell array region. The protective nitride film 150 covers the side surface and the upper surface of the peripheral insulating layer 130 so that the stepped portion is covered.

The inner circumferential side surface in the guard ring groove 132 is formed of the side surface of the conductive layer that forms the counter electrode 170, as shown in FIG. 5, and the sidewall conductive film 133c, which is made of the same material as that of each tubular storage electrode, is formed on the side surface of the conductive layer.

In the structure of the present embodiment, the surface in the guard ring groove 132 is covered with the protective nitride film 150. Therefore, when the interlayer insulating film inside the guard ring groove 132 is etched away in a wet etching process in the manufacturing procedure, the etchant will not penetrate the peripheral insulating layer 130, and no void will be produced.

The protective nitride film 150 can be readily formed by using lithography technique and dry etching technique.

A support film pattern may be formed to prevent the tubular storage electrodes 133a from collapsing when the wet etching is carried out. The support film pattern can be formed by patterning the protective nitride film 150 in such a way that the protective nitride film 150 that covers the surface in the guard ring groove 132 and the peripheral insulating layer 130 is left, and at the same time, the protective nitride film 150 in the memory cell array region (the region inside the guard ring groove 132) has a particular shape.

Assuming that a support nitride film 140 for forming the support film pattern is provided separately before the protective nitride film 150 is formed, the support film pattern formed of the two layers (140 and 150) can be formed in the memory cell array region, as shown in FIG. 5, by stacking the protective nitride film 150 on the support nitride film 140 and patterning the layers together. In this way, the strength of the support film pattern can further be increased, whereby it is possible to effectively prevent the tubular storage electrodes from collapsing when the wet etching is carried out.

The structure of the semiconductor device of the present embodiment and a method for manufacturing the same will be described below in detail with reference to the drawings.

First, a semiconductor substrate (not shown) on which memory cell transistors, transistors in a peripheral circuit, and wiring lines are formed is prepared.

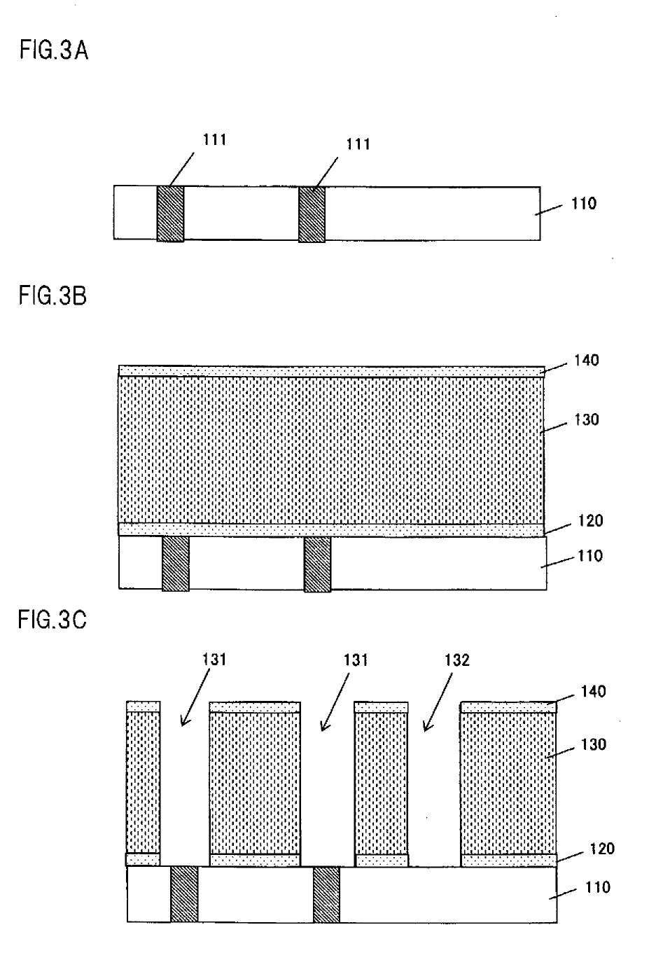

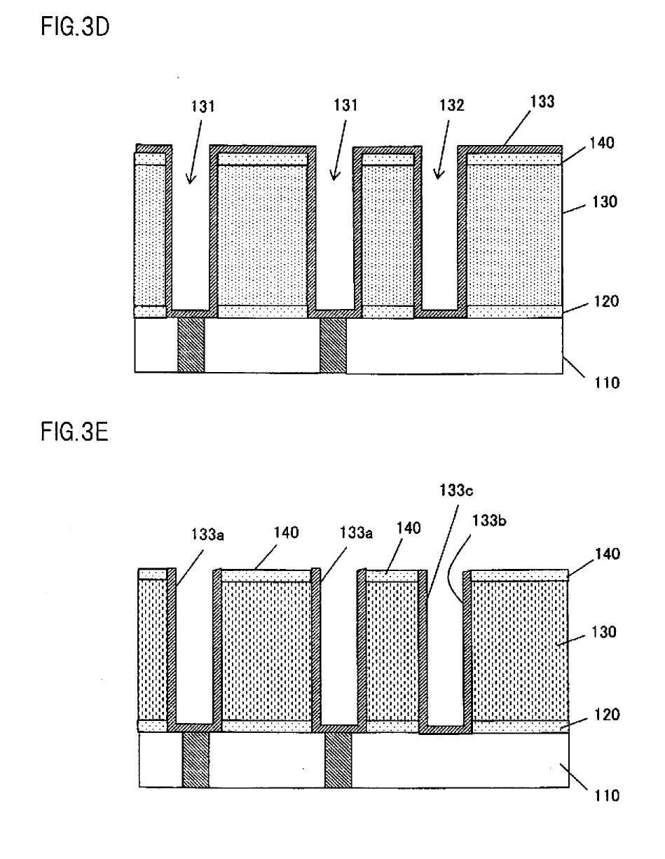

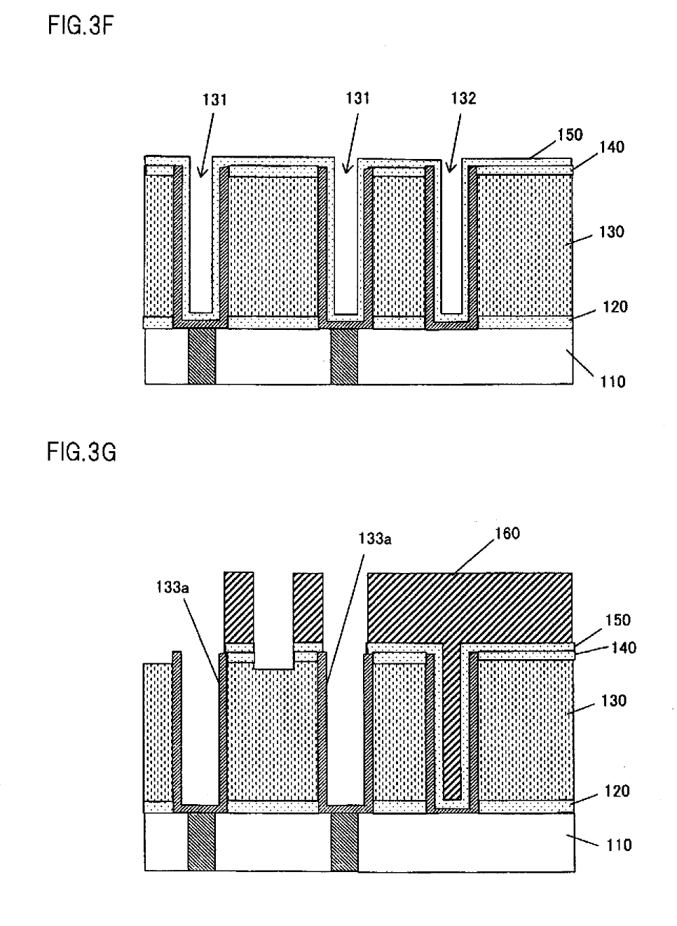

Thereafter, an interlayer insulating film 110 formed of a silicon oxide film or any other suitable film is formed on the semiconductor substrate, and contact plugs 111 to be electrically connected to the memory cell transistors are formed in accordance with a typical method, as shown in FIG. 3A.

Thereafter, a stopper nitride film 120, an interlayer insulating film 130 formed of a silicon oxide film, and a support nitride film 140 are sequentially formed, as shown in FIG. 3B. The stopper nitride film 120 functions as an etching stopper when holes in which tubular storage electrodes are formed and a guard ring groove are formed later. The support nitride film 140 forms an underlying layer of a support film pattern later. The stopper nitride film 120 and the support nitride film 140 can be a silicon nitride film or a silicon oxynitride film and formed by using a method similar to that used to form a protective nitride film 150, which will be described later. The thickness of the stopper nitride film 120 can be set as appropriate in consideration of the etching selection ratio of the stopper nitride film 120 to the interlayer insulating film and the plugs, and the thickness of the support nitride film 140 can be set as appropriate in consideration of the controllability at the time of the film deposition, the precision in the patterning, the effect of preventing the tubular storage electrodes from collapsing, and other factors.

Thereafter, a typical method based on lithography technique and dry etching technique is used to form holes 131 for forming the tubular storage electrodes and a guard ring groove 132 that surrounds a memory cell array region, as shown in FIG. 3C.

Thereafter, a conductive film 133 is formed over the surface of the resultant structure including the surfaces in the holes 131 and in the guard ring groove 132, as shown in FIG. 3D. The conductive film can be, for example, a titanium nitride (TiN) film or a doped polycrystalline silicon (DOPOS) film.

Thereafter, the conductive film 133 on the support nitride film 140 other than those in the holes 131 and the guard ring groove 132 is removed, as shown in FIG. 3E. The removal can be carried out by using chemical mechanical polishing (CMP) or etchback after the holes and the guard ring groove are filled with an insulating material, a resist, or any other suitable protective material. Thereafter, the protective material is removed. Conductive films 133a left in the holes 131 form the tubular storage electrodes. The outer circumferential conductive film in the guard ring groove forms a sidewall conductive film 133b, and the inner circumferential conductive film in the guard ring groove forms a sidewall conductive film 133c.

Thereafter, a protective nitride film 150 is formed over the surface of the resultant structure including the surface in the guard ring groove 132, as shown in FIG. 3F. The protective nitride film 150 can be a silicon nitride film or a silicon oxynitride film (SiON film).

The protective nitride film 150 is desirably a dense film having a sufficient selectivity against the oxide film under the etchant used in wet etching which will be carried out later, and having least possible minute defects and crystal grains. From this point of view, the film deposition is preferably carried out by using a source gas containing NH₃ and SiH₂Cl₂ in low-pressure CVD at a temperature ranging from 600 to 700° C. and a pressure ranging from 0.1 to 0.5 Torr (13.3 to 66.7 Pa). A silicon oxynitride film can be formed by adding nitrogen oxide (N₂O) gas to the source gas, and carrying out deposition under the conditions similar to those described above.

The thickness of the thus formed protective nitride film 150 is preferably 10 nm or greater. When the protective nitride film 150 is too thin, it is difficult to provide a sufficient protection effect in the following wet etching process. Conversely, when the protective nitride film is too thick relative to the inner diameter of each of the holes 131, the holes 131 are filled with the protective nitride film, and it is difficult to remove the protective nitride film in the holes 131 in the following process. From this point of view, the film thickness of the protective nitride film 150 is preferably smaller than half the inner diameter of each of the holes 131 measured after the conductive film 133 is formed, more preferably 40% of the inner diameter or smaller, still more preferably 30% or smaller. For example, when the inner diameter of each of the holes 131 measured after the conductive film 133 is formed is 200 nm, the film thickness of the protective nitride film can be set within a range from 10 nm inclusive to 100 nm exclusive.

Thereafter, lithography technique and dry etching technique are used along with a resist pattern 160 as a mask to pattern the support nitride film 140 and the protective nitride film 150 at the same time, as shown in FIG. 3G.

By the patterning process, in the guard ring groove 132 and the area outside thereof, the conductive film 133 (sidewall conductive films 133b and 133c) in the guard ring groove 132 is covered with the protective nitride film 150, and the upper surface of the interlayer insulating film 130 outside the guard ring groove is covered with the stacked film formed of the protective nitride film 150 and the support nitride film 140. Thus, the side surface (the outer circumferential stepped portion of the guard ring groove 132) and the upper surface of the interlayer insulating film 130 outside the guard ring groove 132 are covered with the protective nitride film 150, and thereby the interlayer insulating film 130 is protected from the etchant in the following wet etching process.

On the other hand, in the memory cell array region, a support film pattern formed of the support nitride film 140 and the protective nitride film 150 is formed in the patterning process. The support film pattern is formed in such a way that it comes into contact with both upper ends of adjacent tubular storage electrodes 133a. The thus formed support film pattern prevents the tubular storage electrodes 133a from collapsing in the following wet etching process. As will be described later, a patterned portion may also be formed in such a way that it comes into contact with the upper end of each of the tubular storage electrodes 133a disposed along the outer side of the memory cell array region and the upper end of the inner circumferential sidewall conductive film 133c of the guard ring groove.

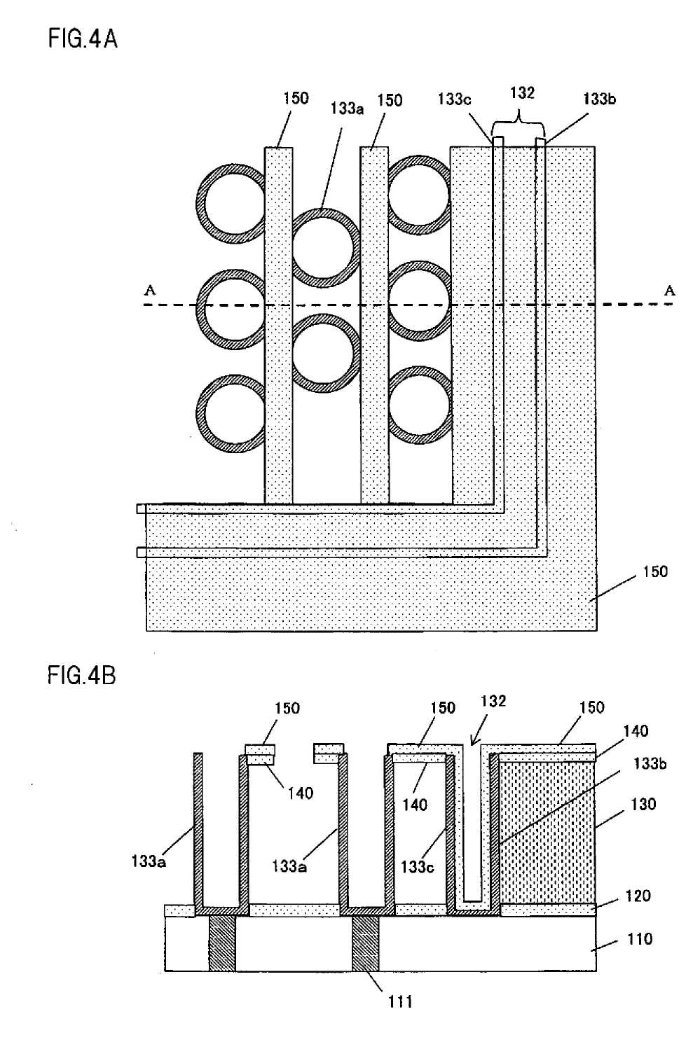

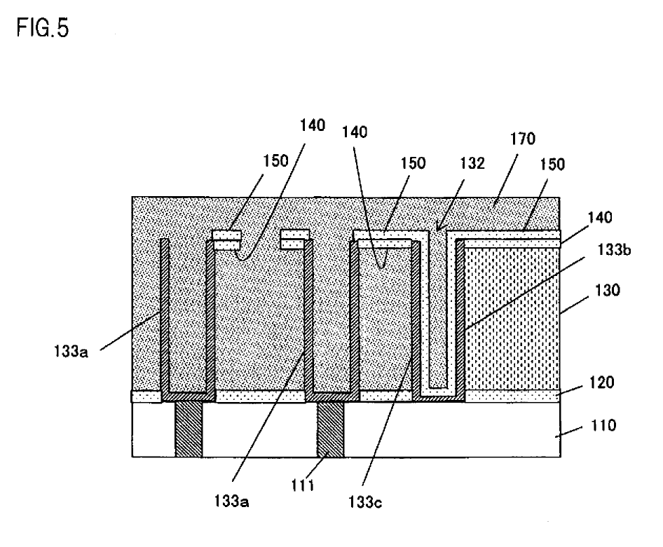

Thereafter, the resist pattern 160 is removed, and then a chemical liquid containing a solution of hydrogen fluoride (HF) in water (hydrofluoric acid, HF concentration ranges from 10 to 50% by mass) is used to carry out wet etching to remove the interlayer insulating film 130 inside the guard ring groove. As a result, the structure shown in FIGS. 4A and 4B is provided. FIG. 4A is a plan view and FIG. 4B is a cross-sectional view taken along the line A-A shown in FIG. 4A. FIGS. 3A to 3G correspond to the cross-sectional view taken along the line A-A shown in FIG. 4A.

As shown in FIGS. 4A and 4B, the upper surface of the interlayer insulating film 130 outside the guard ring groove 132 is covered with the protective nitride film 150 and the support nitride film 140, and the side surface of the interlayer insulating film 130 (the outer circumferential stepped portion of the guard ring groove 132) is covered with the protective nitride film 150 with the intervention of the sidewall conductive film 133b. Therefore, in the wet etching process of removing the interlayer insulating film inside the guard ring groove 132, the etchant will not penetrate the interlayer insulating film outside the guard ring groove 132, and no void will be produced in the interlayer insulating film.

On the other hand, in the memory cell array region (the area inside the guard ring groove 132), the support film pattern formed of the stacked film including the protective nitride film 150 and the support nitride film 140 is formed. Therefore, in the wet etching process of removing the interlayer insulating film inside the guard ring groove 132, the tubular storage electrodes 133a will not collapse. The support film pattern may alternatively be formed of the support nitride film 140 alone. However, the support film pattern formed of the stacked film has a further increased strength, which can more effectively prevent the tubular storage electrodes from collapsing.

In the example shown in FIG. 4A, the support film pattern is shaped into a stripe pattern that comes into contact with both upper ends of adjacent tubular storage electrodes 133a. Further, the tubular storage electrodes 133a disposed along the outer side of the memory cell array region are supported by a patterned portion in contact with the upper end of each of the tubular storage electrodes 133a described above and the upper end of the inner circumferential sidewall conductive film 133c in the guard ring groove 132.

The support film pattern is not limited to the stripe shape described above, but can have an arbitrary shape to the extent that the shape provides the effect of preventing the tubular storage electrodes from collapsing. It is however noted that, to provide a sufficient collapse prevention effect, the pattern desirably has a shape extending from the upper end of each of the tubular storage electrodes to the upper end of at least one of the other tubular storage electrodes adjacent to the tubular storage electrode, the shape being in contact with both the upper ends. The shape of the pattern desirably does not overlap with the inner region of any of the tubular storage electrodes to provide sufficient storage capacity. The tubular storage electrodes disposed along the outer side of the memory cell array region may be supported by the patterned portion in contact with the upper end of each of the tubular storage electrodes described above and the upper end of the inner circumferential sidewall conductive film 133c in the guard ring groove 132, as shown in FIG. 4A. To quickly and sufficiently remove the interlayer insulating film inside the guard ring groove in the wet etching, the pattern preferably has an opening that allows the interlayer insulating film to be sufficiently exposed, and the pattern desirably has an opening that allows part of the interlayer insulating film along the outer circumferential surface of each of the tubular storage electrodes to be exposed.

Thereafter, a dielectric film (not shown) is formed on the exposed surface to cover the inner and outer side surfaces of each of the tubular storage electrodes 133a, and then a counter electrode 170 is formed on the dielectric film, as shown in FIG. 5. The counter electrode is formed to fill each of the tubular storage electrodes 133a, the gap between the tubular storage electrodes, the gap between the tubular storage electrodes disposed along the guard ring and the inner circumferential sidewall conductive film 133c in the guard ring groove, and the guard ring groove 132, the dielectric film being disposed between the counter electrode and the respective tubular storage electrodes. The dielectric film and the counter electrode 170 formed in the portion outside the guard ring groove 132 are patterned as required. As a result, capacitors formed of the tubular storage electrodes 133a, the dielectric film (not shown), and the counter electrode 170 are provided. The dielectric film can be made of a typical capacitor insulating film material, such as aluminum oxide, tantalum oxide, hafnium oxide, zirconium oxide, or other metal oxides, and can be formed by using a typical method capable of isotropic film deposition according to the material used. The counter electrode 170 can be made of a typical capacitor electrode material, such as TiN, and can be formed by using a typical method capable of isotropic film deposition according to the material used.

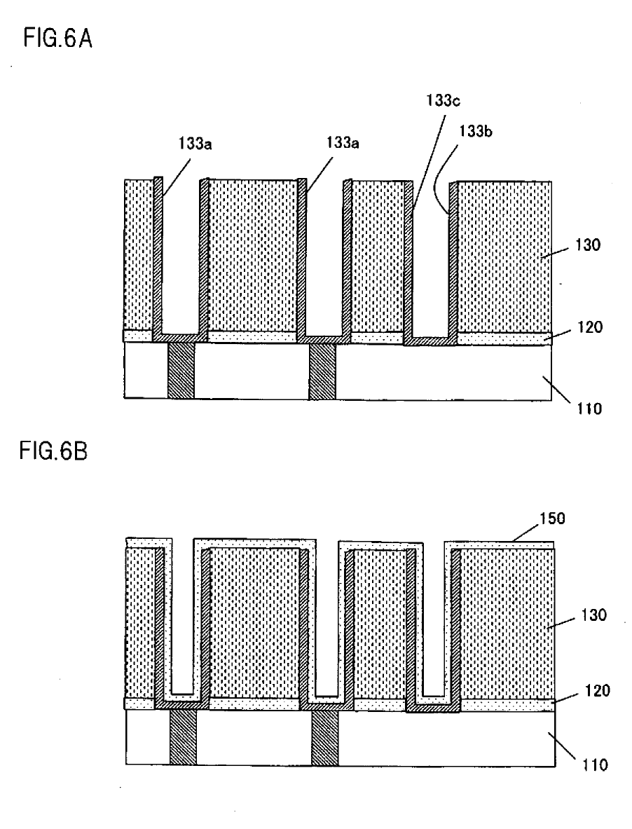

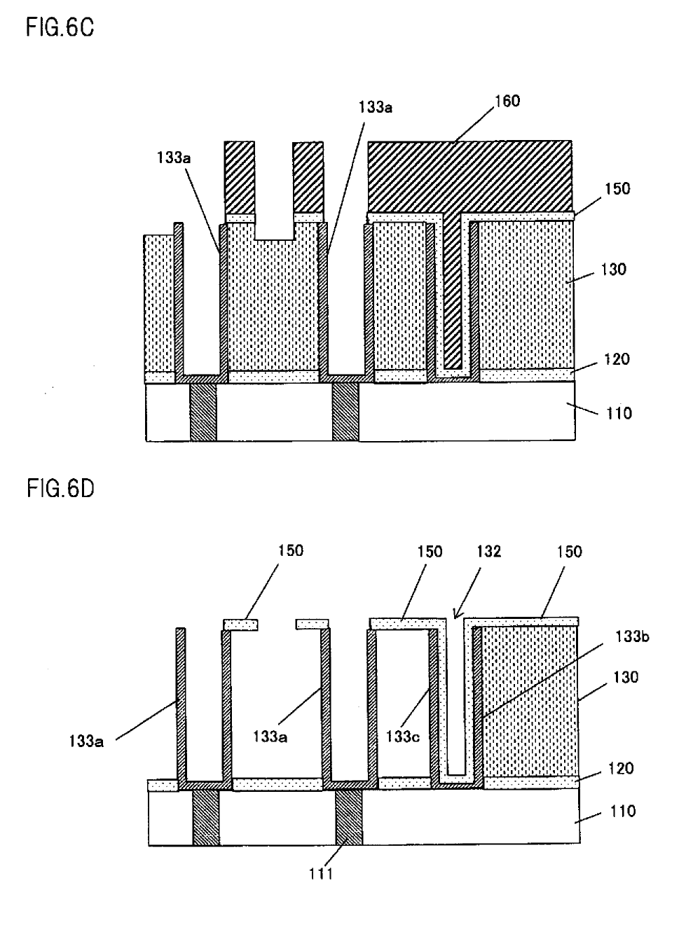

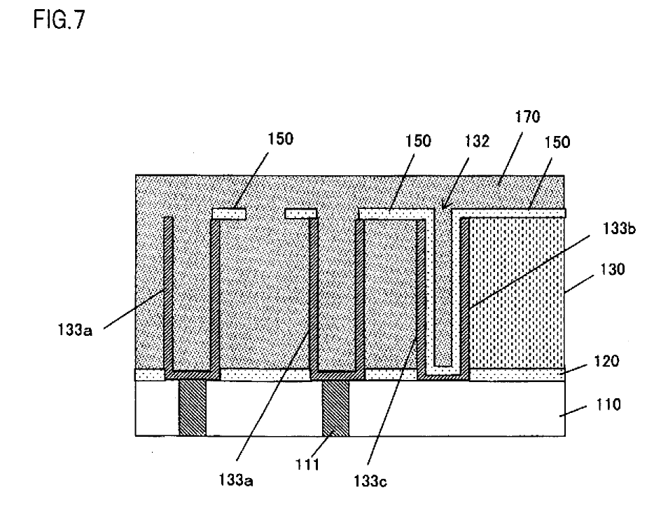

While the above embodiment has been described with reference to the case where the support pattern for preventing the tubular storage electrodes 133a from collapsing is formed of the stacked film including the support nitride film 140 and the protective nitride film 150, the support pattern may be formed of the protective nitride film 150 alone without the support nitride film 140, as shown in FIG. 7. In this embodiment, the protective nitride film 150 covers the peripheral insulating layer 130 and forms the support pattern, whereby the protective nitride film 150 alone serves to not only protect the peripheral insulating layer 130 but also prevent the tubular storage electrodes 133a from collapsing. In this embodiment, the step of forming the support nitride film 140 can be omitted, whereby the manufacturing processes can be simplified. The semiconductor device of this embodiment can be manufactured by using the same method as that used in the embodiment described above except that the support nitride film 140 is not provided, as shown in FIGS. 6A to 7. That is, the steps of forming the structure shown in FIG. 6A and the steps of forming the structures shown in FIGS. 6B, 6C, 6D, and 7 can be the same steps of forming the structure shown in FIG. 3E and steps of forming the structures shown in FIGS. 3F, 3G, 4B, and 5, respectively, except the formation of the support nitride film 140.

It is apparent that the present invention is not limited to the above embodiments, but may be modified and changed without departing from the scope and spirit of the invention.

What is claimed is:

1. A semiconductor device comprising:
a memory cell array region including a plurality of memory cells;
an annular groove surrounding the memory cell array region;
a protective insulating film covering the inner wall of the annular groove, and
a conductor filling the annular groove.

2. The semiconductor device according to claim 1, wherein the protective insulating film is a silicon nitride film or a silicon oxynitride film.

3. The semiconductor device according to claim 1, wherein the outer circumferential side surface in the annular groove is formed of a side surface of a peripheral insulating layer surrounding the memory cell array region; and
the protective insulating film covers the side surface and the upper surface of the peripheral insulating layer.

4. The semiconductor device according to claim 3, wherein the peripheral insulating layer is formed of a silicon oxide film.

5. The semiconductor device according to claim 1, wherein each of the memory cells includes a capacitor;
the capacitor comprises:
a tubular storage electrode,
a dielectric film covering the inner side surface and the outer side surface of the tubular storage electrode, and
a counter electrode on the dielectric film;
the outer circumferential side surface in the annular groove is formed of a side surface of a peripheral insulating layer surrounding the memory cell array region;
the inner circumferential side surface in the annular groove is formed of a side surface of an inner conductive layer;
a sidewall conductive film made of the same material as that of the storage electrode is formed on the side surface of the peripheral insulating layer;
the protective insulating film covers the side surface and the upper surface of the peripheral insulating layer, the sidewall conductive film being disposed between the protective insulating film and the side surface of the peripheral insulating layer; and
the counter electrode, the conductor filling the annular groove, and the side surface of the inner conductive layer are made of the same material and formed integrally with one another.

6. The semiconductor device according to claim 5, wherein a support insulating film pattern is formed from the upper end of each of the tubular storage electrodes to the upper end of at least one of the other tubular storage electrodes adjacent to the tubular storage electrode, the support insulating film pattern being in contact with both the upper ends, without overlapping with the inner region of any of the tubular storage electrodes.

7. The semiconductor device according to claim 6, wherein the support insulating film pattern is made of the same material as that of the protective insulating film.

8. The semiconductor device according to claim 7, wherein the support insulating film pattern is continuous with the protective insulating film.

9. The semiconductor device according to claim 6, wherein the support insulating film pattern is formed of a stacked film including a first support film pattern and a second support film pattern on the first support film pattern; and
the second support film pattern is made of the same material as that of the protective insulating film.

10. The semiconductor device according to claim 5, wherein the tubular storage electrode is made of titanium nitride or doped polycrystalline silicon.

11. The semiconductor device according to claim 1, wherein the thickness of the protective insulating film is at least 10 nm.

12. A semiconductor device comprising:
a memory cell array region including a plurality of memory cells;
a peripheral insulating layer provided on an underlying insulating film;
an annular stepped portion formed of a side surface of the peripheral insulating layer, the annular stepped portion surrounding the memory cell array region; and
a protective insulating film formed on the side surface and the upper surface of the peripheral insulating layer, the protective insulating film covering the stepped portion,
wherein each of the memory cells includes a capacitor comprising
a tubular storage electrode connected to a plug passing through the underlying insulating film,
a dielectric film covering the inner side surface and the outer side surface of the storage electrode, and
a counter electrode on the dielectric film.

13. The semiconductor device according to claim 12, wherein the protective insulating film is a silicon nitride film or a silicon oxynitride film; and
the peripheral insulating layer is a silicon oxide film.

14. The semiconductor device according to claim 12, wherein a sidewall conductive film made of the same material as that of the storage electrode is formed on the side surface of the peripheral insulating layer, the side surface forming the stepped portion; and
the protective insulating film is provided over the side surface of the peripheral insulating layer, the sidewall conductive film being disposed between the protective insulating film and the side surface of the peripheral insulating layer.

15. The semiconductor device according to claim 12, wherein a support insulating film pattern is formed from the upper end of each of the tubular storage electrodes to the upper end of at least one of the other tubular storage electrodes adjacent to the tubular storage electrode, the support insulating film pattern being in contact with both the upper ends, without overlapping with the inner region of any of the tubular storage electrodes.

16. A method for manufacturing a semiconductor device comprising:
forming an underlying insulating film on a semiconductor substrate;
forming a plurality of plugs passing through the underlying insulating film;
forming an interlayer insulating film on the underlying insulating film;
forming a plurality of holes and an annular groove in the interlayer insulating film, the holes reaching the respective plugs, the annular groove surrounding the holes and reaching the underlying insulating film;
forming a first conductive film on the surface including the inner surfaces of the holes and the annular groove;
removing the first conductive film other than those in the holes and the annular groove such that a plurality of tubular conductors formed of the first conductive film are left in the holes;
forming a protective insulating film covering the inner surface of the annular groove and the interlayer insulating film outside the annular groove;
carrying out isotropic etching with the protective insulating film used as a mask to remove the interlayer insulating film portion inside the annular groove such that the tubular conductors are exposed;
forming a dielectric film on the inner side surface and the outer side surface of each of the tubular conductors; and
forming a second conductive film on the dielectric film.

17. The method for manufacturing a semiconductor device according to claim 16, wherein a silicon nitride film or a silicon oxynitride film is formed as the protective insulating film.

18. The method for manufacturing a semiconductor device according to claim 17, wherein the protective insulating film is formed by using low-pressure CVD at a temperature ranging from 600 to 700° C.

19. The method for manufacturing a semiconductor device according to claim 16, wherein the protective insulating film is formed to be at least 10 nm in thickness.

20. The method for manufacturing a semiconductor device according to claim 16, wherein a silicon oxide film is formed as the interlayer insulating film.
